(19) United States
(12) Patent Application Publication
(10) Pub. No.: US 2007/0147017 A1
(43) Pub. Date: Jun. 28, 2007

(54) Integrated electronic module structure for vehicles

(75) Inventor: Junhyoung Eom, Chungnam (KR)

Correspondence Address: John W Renner;Renner Otto Boisselle & Sklar, 1621 Euclid Avenue, Nineteenth Floor, Cleveland, OH, 44115, US

(73) Assignee: YOUNGHWA TECH CO., LTD., Chungnam (KR)

(21) Appl. No.: 10/593,374

(22) PCT Filed: Mar. 18, 2005
(86) PCT No.: PCT/KR05/00786

§ 371 Date: Sep. 19, 2006

(30) Foreign Application Priority Data
Mar. 20, 2004 (KR) 20-2004-0007768

(51) Int. Cl. H05K 7/04

(52) U.S. Cl. 361/809

(57) ABSTRACT

Disclosed is an integrated electronic module structure for vehicles that is constructed as an integrated unit using one multi-pole connector for one wire harness. The integrated module structure includes a first printed circuit board (PCB) having fuses, relay circuits, etc., mounted thereon, a second PCB having input/output (I/O) terminals, and a PCB connecting unit for electrically connecting the first and second PCBs. The first and second PCBs are connected through the connector to form the integrated electronic module structure.

### TECHNICAL FIELD

The present invention relates to an integrated electronic module structure for vehicles, and more particularly to an integrated electronic module structure for vehicles in which first and second printed circuit boards (PCBs) are provided and a circuit connected between the first PCB and I/O terminals of the second PCB and a circuit connected between the second PCB and the I/O connectors of the second PCB are integrated using one multi-pole connector for each wire harness.

### BACKGROUND ART

Generally, electric equipment of a vehicle may be considered as a kind of nervous system. A superior performance of the vehicle can be secured by a normal operation of the electric equipment. This electric equipment includes an electric devices related to the operation an engine and diverse electric components installed in a body of a vehicle except for the engine.

Typically, in order to provide electricity to diverse electronic components and motor driving devices of the vehicle, wires are connected through a junction box, and fuses, relays, etc., are installed in the junction box as protection devices for preventing overload from occurring in a fuel tank, an engine, lighting devices, a warning display device, etc.

In the junction box, wires connected from harnesses to fuses or relay terminals are processed through PCBs, and wires of the PCBs are electrically connected to the harnesses through connectors. This junction box is installed in an engine room and around a driver's seat to provide an improved operation efficiency and reliability of wiring.

Meanwhile, a plurality of small modules for individually controls driver convenience devices of the vehicle are mounted inside the vehicle. An electronic control module includes a plurality of small modules and one or two microcomputers for controlling the modules.

The electronic control module includes modules for basic functions for the driver's convenience such as modules of power window timer control, one-touch power window, door lock control, wiper control, room lamp decay, illumination control, chime bell, battery saver, rear defog control, etc., and modules for diverse optional modules such as modules of rear fog control, shift lock control, keyless entry, daytime running light, etc.

The junction box and the electronic control module are fabricated into an integrated system to perform a function of transmitting and distributing all kinds of current. Conventionally, the junction box and the electronic control module are electrically connected to each other to form a single package product. That is, circuits that can be connected by wires among circuits of the junction box and the electronic control module are constructed as an integrated unit to achieve a more efficient circuit design.

That is, the size of the system can be minimized to match the vehicle design with duplicate electric connection through an outside removed by separately preparing the junction box and the electronic control module, mechanically fixing their male and female terminals to face the corresponding components for their mutual electric connection, and arranging the junction box and the electronic control module in a laminated body.

An example of the conventional electronic control module is disclosed in Korean Patent Unexamined Publication No. 2000-9545.

According to this conventional electronic control module, independent circuits of a junction box part and an electronic control module part are provided with independent connectors, respectively, and connected to an outside through circuit construction using the independent connectors.

Accordingly, many connectors should be provided. For example, in the case in which the circuit should be divided into two or three kinds of wire harnesses, connectors the number of which is as many as ‘the number of cases ×2’ are required (for example, if two kinds of harnesses exist, four connectors are required, and if three kinds of harnesses exist, six connectors are required). This causes the size of the module structure to be increased and the vehicle assembling work for installing the connectors to be complicated.

Additionally, even though the junction box and the electronic control unit are constructed into a circuit construction (for example, integrated circuit part on the PCB), the circuit can be divided into two or three harnesses only, and thus more than 100 circuits may be constructed in consideration of the whole function of the system. This makes it impossible to solve the vehicle maker's request for the simple process and the reduction of the manufacturing cost by reducing the number of connectors.

### BRIEF DESCRIPTION OF THE DRAWINGS

The above objects, other features and advantages of the present invention will become more apparent by describing the preferred embodiments thereof with reference to the accompanying drawings, in which:

FIG. 1 is an exploded perspective view illustrating the schematic construction of an integrated electronic module structure for vehicles according to an embodiment of the present invention;

FIG. 2 is a side sectional view of the integrated electronic module structure according to an embodiment of the present invention;

FIG. 3 is an exploded perspective view illustrating the detailed construction of a junction box according to an embodiment of the present invention; and

FIG. 4 is a schematic perspective view illustrating the construction of a conventional integrated electronic module.

### DISCLOSURE OF INVENTION

### Technical Problem

Therefore, the present invention has been made to solve the above-mentioned problems occurring in the prior art, and an object of the present invention is to provide an integrated electronic module structure for vehicles that has a simple construction and that can reduce the manufacturing cost.

Particularly, the present invention is focused on the scheme for minimizing the number of connectors in relation to the wire harness with the size of the structure reduced by providing first and second PCBs as the junction box circuit and the electronic control module circuit and constructing the junction box and the electronic control module using a multi-pole connector for each harness.

Additional advantages, objects, and features of the invention will be set forth in part in the description which follows and in part will become apparent to those having ordinary skill in the art upon examination of the following or may be learned from practice of the invention.

### Technical Solution

In order to accomplish the above-mentioned objects, an integrated electronic module structure for vehicles according to the present invention is constructed using one multi-pole connector for one wire harness. The integrated electronic module structure for vehicles according to the present invention includes a first printed circuit board (PCB) having fuses, relay circuits, etc., mounted thereon, a second PCB having input/output (I/O) terminals, and a PCB connecting unit for electrically connecting the first and second PCBs.

The connector comprises a multi-pole connector. According to the integrated electronic module structure for vehicles according to the present invention, a circuit connected between the first PCB and I/O terminals of the second PCB and a circuit connected between the second PCB and the I/O connectors of the second PCB are integrated in one multi-pole connector, resulting in that the first PCB and the second PCB can be constructed using one multi-pole connector for each wire harness.

It is preferable that the first PCB is a junction box for vehicles, and the second PCB is an electronic control module for vehicles.

Preferably, the PCB connecting unit comprises connecting pins.

Preferably, the integrated electronic module structure for vehicles according to the present invention is constructed in a manner that the connectiing pins are directly inserted into the first PCB and into a part corresponding to the I/O terminals of the second PCB, then soldered, and external injection molded parts are formed to have connectors that constitute a pair of male and female connectors together with the multi-pole connectors of the wire harnesses.

### Advantageous Effects

As apparent from the above description, it will be apparent that the present invention has the advantages in that by constructing the junction box and the electronic control module as an integrated unit, the circuit construction is simplified, and the manufacturing cost of the module is reduced.

Additionally, according to the present invention, by constructing the junction box circuit and the electronic control module circuit in a connector using one multi-pole connector for each harness, the size of the electronic module is reduced and the connector is minimized.

The forgoing embodiments are merely exemplary and are not to be construed as limiting the present invention. The present teachings can be readily applied to other types of apparatuses. The description of the present invention is intended to be illustrative, and not to limit the scope of the claims. Many alternatives, modifications, and variations will be apparent to those skilled in the art.

### Mode for the Invention

Now, an integrated electronic module structure for vehicles according to a preferred embodiment of the present invention will be described in detail with reference to the annexed drawings.

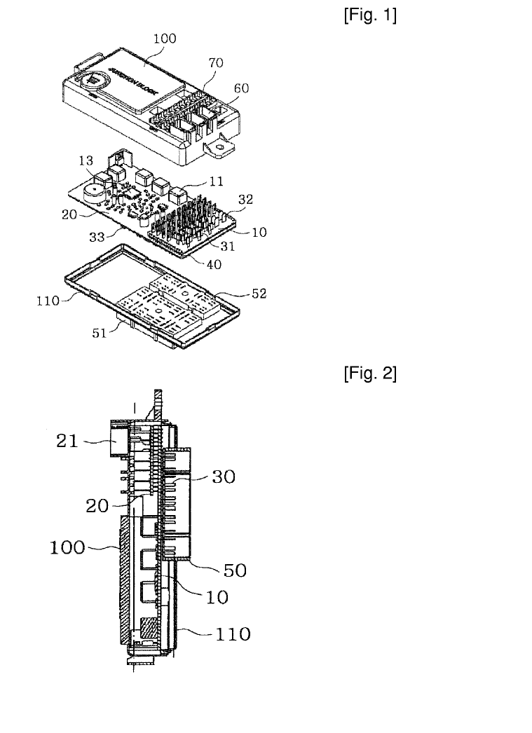

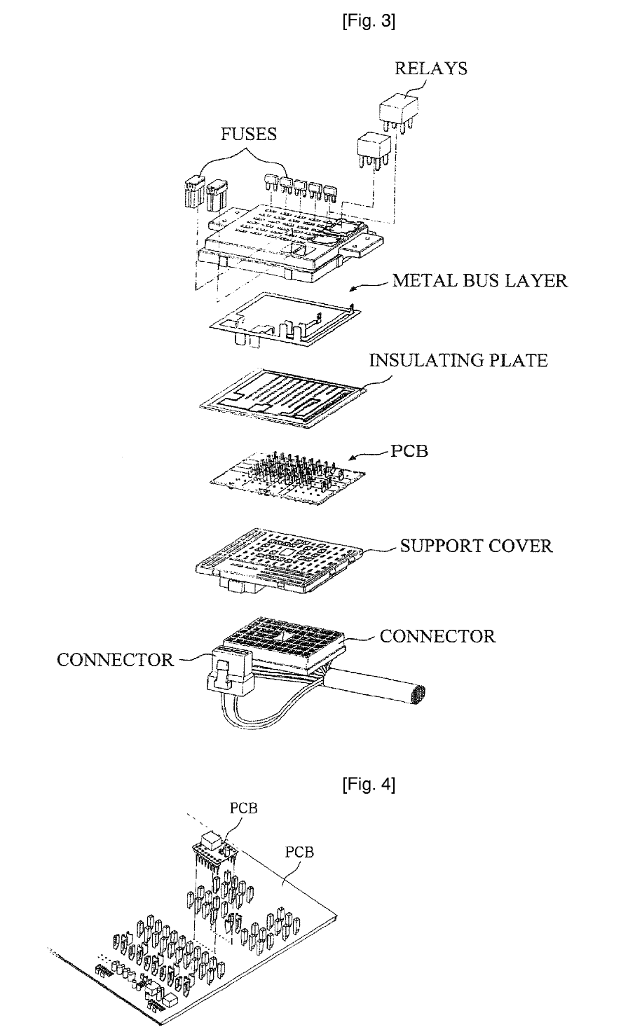

FIG. 1 is an exploded perspective view illustrating the schematic construction of an integrated electronic module structure for vehicles according to an embodiment of the present invention.

In the embodiment of the present invention, first and second PCBs 10 and 20 are prepared as an upper PCB and a lower PCB, respectively. The first and second PCBs 10 and 20 are laminated and electrically connected together.

The upper PCB 10 is a junction box for vehicles on which components such as fuses, relays, etc., are mounted. An I/O terminal 33 of the upper PDB 10 is constructed on the lower PCB 20 that is the other PCB, and the upper and lower PCBs are constructed to share male and female I/O terminals 31 and 32 in circuit. In consideration of the number of circuits provided at the sides of the upper PCB 10, the upper PCB 10 is located to match one end part of the lower PCB 20, and then the upper PCB 10 and the lower PCB 20 are connected by connecting pins 40 to form an electric circuit.

The lower PCB 20 is an electronic control module for vehicles. In order to reduce the influence of electromagnetic waves from a power supply unit that transmits a large amount of current and to provide advantage in automatically assembling electronic components, one part of the lower PCB 20 is constructed to form functional modules in closer order, and on the other part of the lower PCB 20, an I/O connector (not illustrated) is arranged to connect to the I/O connector of the upper PCB in a horizontal direction.

In order to divide the circuit into two or three harnesses according to the characteristic of the vehicle, a circuit connected between the junction box of the upper PCB 10 and the I/O terminals of the lower PCB, and a circuit connected between the electronic control module of the lower PCB 20 and the I/O connectors of the lower PCB 20 are integrated, so that the junction box circuit and the electronic control module circuit are constructed in one connector using one multi-pole connector housing 51 or 52 for each harness to reduce the size of the module structure and to minimize the connector.

An upper injection molded part 100 is provided on the upper PCB 10 and the lower PCB 20. This upper injection molded part is provided with a relay connection part 60 and a fuse connection part 70 connected to the junction box of the upper PCB 10, which are connected to various kinds of relays and fuses. Meanwhile, a lower injection molded part 110 of the PCB includes the multi-pole housings 51 and 52 in structure.

FIG. 2 is a side sectional view of the integrated electronic module structure according to an embodiment of the present invention.

As illustrated in FIG. 2, the upper PCB 20 that is the junction box is electrically connected to the lower PCB 20 that is the electronic control module by the connecting pins.

In integrating the junction box and the electronic control module as described above, an I/O circuit is constructed by one connector for each harness, and in order to reduce the number of circuits of the two parts, the junction box circuit and the I/O circuit coming from the electronic module are directly inserted into the PCB. As a result, the unnecessary header connector can be reduced.

In the embodiment of the present invention, the upper and lower PCBs are constructed in a laminated structure. However, the scope of the present invention is not limited to the embodiment. In the case in which the circuit construction of the junction box and the circuit construction of the electronic control module are not complicated according to the kind of vehicle, the junction box and the electronic control module can be constructed on one lower PCB, and in this case, the connectors between the lower part of the junction box and the electronic control module may be arranged on one PCB.

Additionally, for the spatial arrangement, plug relays may be adopted as the power TR and PCB relays, or installation positions of the fuses may be changed.

1. An integrated electronic module structure for vehicles constructed using one connector for each wire harness, the structure comprising:
a first printed circuit board (PCB) having fuses and relay circuits mounted thereon;
a second PCB having input/output (I/O) terminals; and
a PCB connecting unit for electrically connecting the first and second PCBs.

2. The integrated electronic module structure as claimed in claim 1, wherein the connector comprises a multi-pole connector, and
a circuit connected between the first PCB and the I/O terminals of the second PCB, and a circuit connected between the second PCB and I/O connectors of the second PCB are integrated in one multi-pole connector, and thus the first PCB and the second PCB can be constructed using one multi-pole connector for each wire harness.

3. The integrated electronic module structure, as claimed in claim 1, wherein the first PCB is a junction box for vehicles.

4. The integrated electronic module structure, as claimed in claim 1, wherein the second PCB is an electronic control module for vehicles.

5. The integrated-electronic module structure as claimed in claim 1, wherein the PCB connecting unit is composed of connecting pins.

6. The integrated electronic module structure as claimed in claim 5, wherein the connecting pins are directly inserted into the first PCB and into a part corresponding to the I/O terminals of the second PCB, then soldered, and external injection molded parts are formed to have connectors that constitute a pair of male and female connectors together with the multi-pole connectors of the wire harnesses.

7. The integrated electronic module structure, as claimed in claim 2, wherein the first PCB is a junction box for vehicles.

8. The integrated electronic module structure, as claimed in claim 2, wherein the second PCB is an electronic control module for vehicles.

9. The integrated electronic module structure, as claimed in claim 2, wherein the PCB connecting unit is composed of connecting pins.

10. The integrated electronic module structure as claimed in claim 9, wherein the connecting pins are directly inserted into the first PCB and into a part corresponding to the I/O terminals of the second PCB, then soldered, and external injection molded parts are formed to have connectors that constitute a pair of male and female connectors together with the multi-pole connectors of the wire harnesses.
